(19) United States
(12) Patent Application Publication
(10) Pub. No.: US 2011/0244649 A1
(43) Pub. Date: Oct. 6, 2011

(54) METHOD OF MANUFACTURING SEMICONDUCTOR DEVICE

(75) Inventors: Takashi SHIMIZU, Oita-ken (JP); Yusuke Arayashiki, Oita-ken (JP)

(73) Assignee: KABUSHIKI KAISHA TOSHIBA, Tokyo (JP)

(21) Appl. No.: 13/075,624

(22) Filed: Mar. 30, 2011

(30) Foreign Application Priority Data
Mar. 31, 2010 (JP) 2010-084347

(51) Int. Cl. H01L 21/762

(52) U.S. Cl. 438/425; 257/E21.546

(57) ABSTRACT

A method of manufacturing a semiconductor device includes: a process to form an element isolation trench on a semiconductor substrate, the element isolation trench having a crystal plane orientation that is different from a crystal plane orientation on a surface of the semiconductor substrate; a process to deposit, on the semiconductor substrate, one of a metal that promotes generation of oxygen radicals and a metal containing film that promotes generation of the oxygen radicals; a process to oxidize the semiconductor substrate; and a process to remove the one of the metal and the metal containing film.

### CROSS-REFERENCE TO RELATED APPLICATION

This application is based upon and claims the benefit of priority from the prior Japanese Patent Application No. 2010-084347, filed Mar. 31, 2010, the entire contents of which are incorporated herein by reference.

### BACKGROUND

1. Technical Field

Embodiments described herein relate generally to a method of manufacturing a semiconductor device and a method of forming an element isolation trench.

2. Description of the Related Art

The shallow trench isolation (STI) method has been widely used as a method of forming an isolation trench in a semiconductor device. In the STI method, there is drawback that electric properties of a transistor are degraded. Specifically, as an electric field is concentrated at an upper angular part of an element isolation trench formed in a semiconductor substrate, gate withstand voltage is degraded, causing a kink in the current-voltage property of the transistor to be generated.

Therefore, methods have been studied to increase the radius of curvature of the upper angular part of the element trench in order to reduce the concentration of the electric field at the upper angular part. For example, methods have been proposed in which thermal oxidation is performed for a long period or under a high temperature of 1,000° C. or greater after the element isolation trench is formed, and in which oxidation is performed using oxygen radicals after the element isolation trench is formed. However, with such an oxidation for a long period or under a high temperature, the radius of curvature of the element isolation trench does not become large enough, and therefore, the concentration of the electric field is not reduced. In addition, with the oxidation using oxygen radicals, it is relatively difficult to control the amount of the oxygen radicals on a wafer surface because the oxygen radicals are handled in a gaseous phase, causing unsatisfactory in-plane non-uniformity of the oxidation radicals.

### BRIEF DESCRIPTION OF THE DRAWINGS

A more complete appreciation of the invention and many of the attendant advantages thereof will be readily obtained as the same becomes better understood by reference to the following detailed description and the accompanying drawings.

FIG. 1 is a cross-sectional view illustrating a method of manufacturing a semiconductor device according to a first embodiment.

FIG. 2 is a cross-sectional view illustrating the method of manufacturing the semiconductor device according to the first embodiment.

FIG. 3 is a cross-sectional view illustrating the method of manufacturing the semiconductor device according to the first embodiment.

FIG. 4 is a cross-sectional view illustrating the method of manufacturing the semiconductor device according to the first embodiment.

FIG. 5 is a cross-sectional view illustrating the method of manufacturing the semiconductor device according to the first embodiment.

FIG. 6 is a cross-sectional view illustrating a method of manufacturing a semiconductor device according to a comparative example.

FIG. 7 explains one of advantages of the first embodiment.

FIG. 8 is a cross-sectional view illustrating a method of manufacturing a semiconductor device according to a second embodiment.

FIG. 9 is a cross-sectional view illustrating the method of manufacturing the semiconductor device according to the second embodiment.

FIG. 10 is a cross-sectional view illustrating the method of manufacturing the semiconductor device according to the second embodiment.

### DETAILED DESCRIPTION

Various other objects, features and attendant advantages of the exemplary embodiments described herein will be more fully appreciated from the following detailed description when considered in connection with the accompanying drawings in which like reference characters designate like or corresponding parts throughout the several views.

Methods of manufacturing a metal insulator semiconductor (MIS) transistor as an example of a semiconductor device according to the embodiments with respect to the present invention are explained based on the drawings.

### First Embodiment

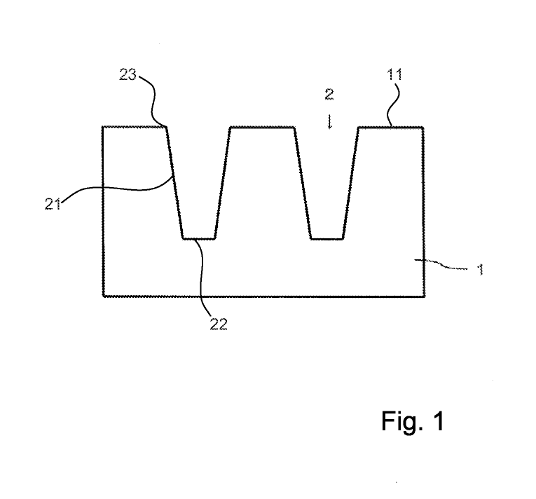

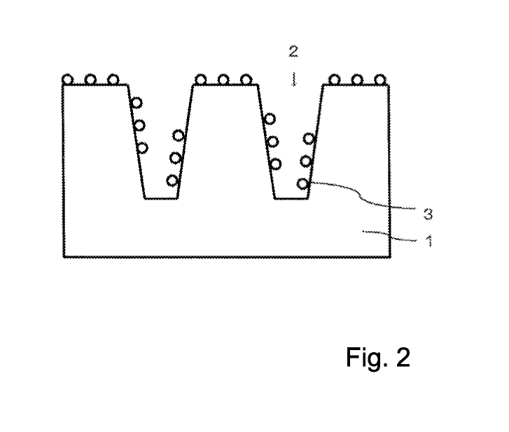

FIGS. 1-5 are cross-sectional views illustrating a method of manufacturing a semiconductor device according to the first embodiment.

As shown in FIG. 1, reactive ion etching (RIE) is performed on a semiconductor substrate 1, which contains silicon as a main component, to form an element isolation trench 2. However, any known method may be applied to form the element isolation trench 2. At this time, various crystal plane orientations are present on a surface 11 of the semiconductor substrate 1, side surfaces 21 and bottom surfaces 22 of the element isolation trench 2 and angular parts 23 of the element isolation trench 2. In particular, different crystal plane orientations are present at the angular parts 23 of the element isolation trench 2. Because each of the angular parts 23 has an angulated shape, a large stress is applied to this area during oxidation. Therefore, the oxidation is more difficult to perform compared with other parts of the element isolation trench 2.

Next, Hafnium (Hf) 3 in the amount of 1E15 atoms/cm² of, for example, is deposited on the semiconductor substrate 1 and the element isolation trenches 2 by sputtering. The Hf is deposited in an area including at least the upper angular part 23 of the element isolation trench 2. The amount of Hf deposited may be equal to or less than 1 atomic layer.

Moreover, by thermally oxidizing the semiconductor substrate 1 for the purpose of reducing damage caused by the RIB process, an oxide film 4 is formed to continuously cover the surfaces 11 of the semiconductor device 1 as well as the side surfaces 21 and bottom surfaces 22 of the element isolation trench 2. The thermal oxidation process is performed, for example, at a temperature of 900° C., a dry oxygen atmosphere and at an oxygen partial pressure of 5 Torr. During this thermal oxidation, the oxidation using the oxygen radicals progresses. The upper angular parts 23 of the element isolation trench 2 are rounded, resulting in increase in the radius of curvature of the element isolation trench 2 compared with the radius of curvature prior to the oxidation using the oxygen radicals. This feature will be discussed in detail later.

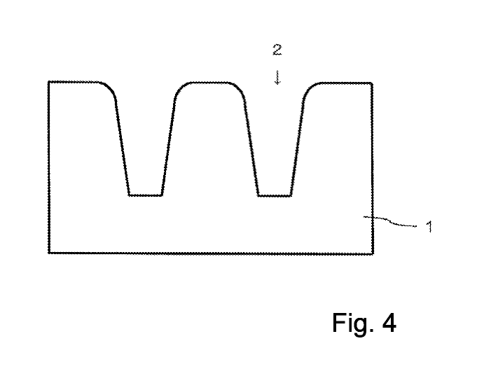

Next, as shown in FIG. 4, by processing the semiconductor substrate 1 with a dilute fluoride solution, the Hf 3 and the oxide film 4 on the semiconductor substrate 1 and the element isolation trench 2 are removed. At this time, only Hf needs to be removed, and the oxide film 4 may remain on the semiconductor substrate 1 or the element isolation trench 2.

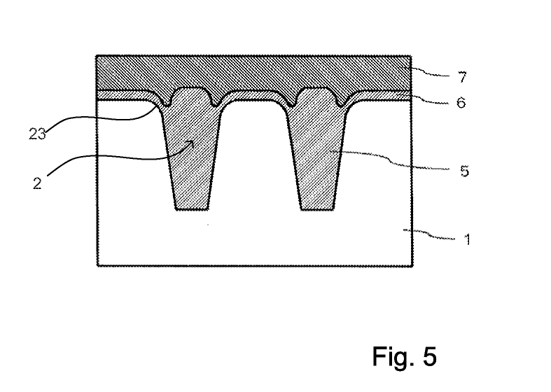

Referring to FIG. 5, the element isolation trench 2 is filled with an element isolation insulating film 5. After the surfaces 11 of the semiconductor substrate 1 is flattened by chemical mechanical polishing (CMP), a gate insulating film 6 is formed on the semiconductor substrate 1. The boundary between the element isolation insulating film 5 and the gate insulating film 6 is not clearly formed. Since the upper angular part 23 of the element isolation trench 2 is rounded to ease stress, the gate insulating film 6 is formed in the vicinity of the upper angular part 23 with a film thickness that is sufficient to suppress an increase in leak current can be suppressed.

Further, as shown in FIG. 5, a gate electrode 7 is formed to cover an area above the upper angular parts 23 of the element isolation trench 2. A transistor is formed thereafter by performing an ion injection using a known method.

According to the present embodiment, because the radius of curvature of the upper angular part 23 of the element isolation trench 2 is large, the concentration of an electric field at the upper angular part 23 of the element isolation trench 2 when a voltage is applied to the gate electrode 7 can be reduced. As a result, degradation of the electric property of the transistor can be suppressed.

In the present embodiment, thermal oxidation is performed while the Hf exists on the semiconductor substrate 1 and the element isolation trench 2. Therefore, the Hf acts as a catalyst, and generation of oxygen radicals is promoted. Because the oxygen radicals are generated in the vicinity of the semiconductor substrate 1 and the element isolation trench 2 to be oxidized, the amount of the oxygen radicals used for oxidation can be easily controlled.

Compared with oxidation using oxygen in a molecular state, oxidation using oxygen radicals has little dependency on the plane orientation of the semiconductor substrate in a formation process of the oxidation film thickness. An oxide film with a uniform film thickness can be formed even on a semiconductor substrate on which different crystal plane orientations are present. Therefore, the oxide film 4 with a uniform film thickness is formed to continuously cover the surface of the semiconductor substrate 1 with different crystal plane orientations, as well as the side surfaces 21 and the bottom surfaces 22 of the element isolation trench 2.

Furthermore, the speed of oxidation with the oxygen radicals is faster than with the oxygen in the molecular state. Therefore, the oxide film 4 is formed with a sufficient thickness at the upper angular part 23 of the element isolation trench 2. At this time, the oxidation penetrates the silicon substrate at the upper angular part 23 of the element isolation trench 2, thereby increasing the radius of curvature at the upper angular part 23 compared with the radius of curvature prior to the oxidation.

In addition, compared with oxidation using the oxygen in the molecular state, it is possible to obtain a large enough radius of curvature by oxidation at a lower temperature and for a shorter period.

As discussed above, because the radius of curvature is large at the upper angular part 23 of the element isolation trench 2 when the gate insulating film 6 is formed, the gate insulation film 6 can be formed with a sufficient film thickness even at the upper angular part 23 of the element isolation trench 2. Therefore, an increase in the leak current from the gate insulating film 6 can be suppressed.

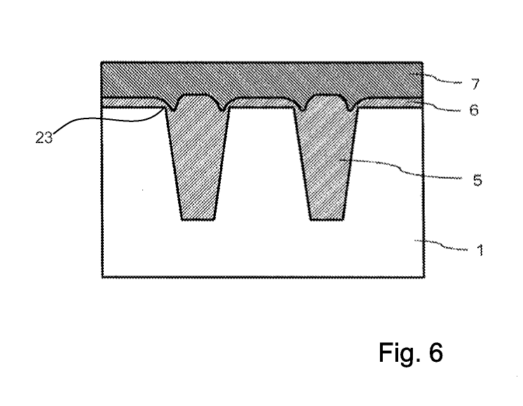

In contrast, when the thermal oxidation is performed without the Hf at the upper angular part 23 of the element isolation trench 2, the radius of curvature at the upper angular part 23 of the element isolation trench 2 is small as shown in FIG. 6. Therefore, the film thickness of the gate insulating film 6 is small in the vicinity of the upper angular part 23 of the element isolation trench 2. This is because the speed of oxidation is slow due to a large compressed stress caused by the oxidation processes in two different directions at the upper angular part 23 of the element isolation trench 2 and because the oxidation largely depends on the crystal plane orientations.

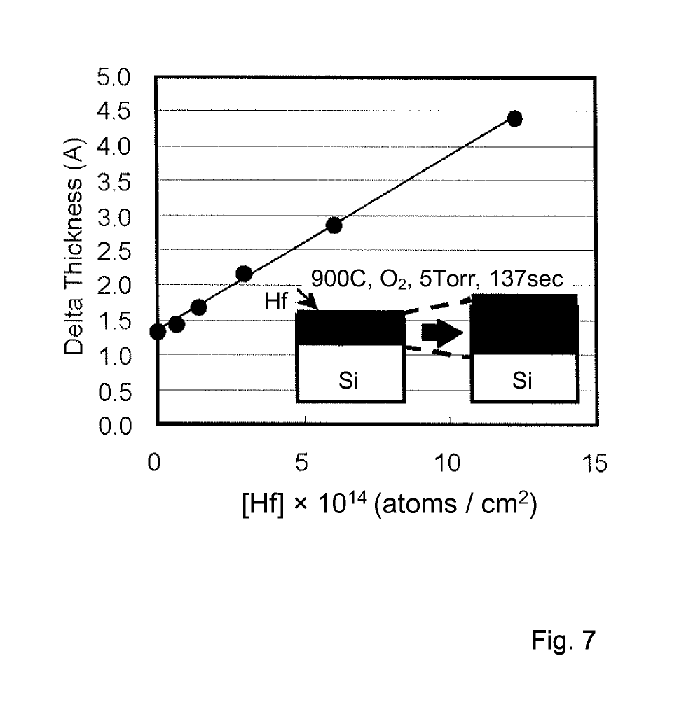

As the amount of Hf is large, the efficiency of generation of oxygen radicals increases, and the thickness of the oxide film 4 increases, resulting in an increase in the radius of curvature at the upper angular part 23 of the element isolation trench 2. That is, by changing the amount of Hf, the film thickness of the oxide film 2 can be easily controlled. FIG. 7 illustrates an amount of increase of the oxide film thickness where the oxidation is performed for 137 seconds under a dry oxygen atmosphere at 900° C. and an oxygen partial pressure of 5 Torr after Hf is deposited by spattering on a 2-nm oxide film formed on a silicon substrate. The horizontal axis indicates the deposited Hf amount, and the vertical axis indicates the increase amount (or delta thickness) of the oxide film thickness. When the Hf amount is zero, an oxide film of approximately 1.3 Å is formed as the oxidation by the oxygen in the molecular state is preformed.

This figure illustrates a case where the Hf is deposited on a 2-nm oxide film. However, similar results are obtained where the Hf is directly deposited on the silicon substrate.

The Hf is deposited in the present embodiment. However, the present embodiment is not limited thereto. A metal containing film that promotes generation of the oxygen radicals may also be used instead of the Hf. For example, a metal silicate film or a metal oxide film or the like containing Hf, such as HfO₂ or HfSiOx, may be available. There is an advantage that HfO₂ and HfSiOx are stable under the oxygen atmosphere during oxidation and are therefore easy to handle.

Moreover, the present embodiment is not limited to the use of Hf. Any metal that promotes the generation of oxygen radicals may be used. For example, zirconium (Zr) and other materials having similar properties may also be used to realize the invention.

### Second Embodiment

The present embodiment differs from the first embodiment in that the Hf is deposited after the element isolation trench 2 is filled with the element isolation insulating film 5. Explanation of processes that are similar to processes explained in the connection with the first embodiment is omitted.

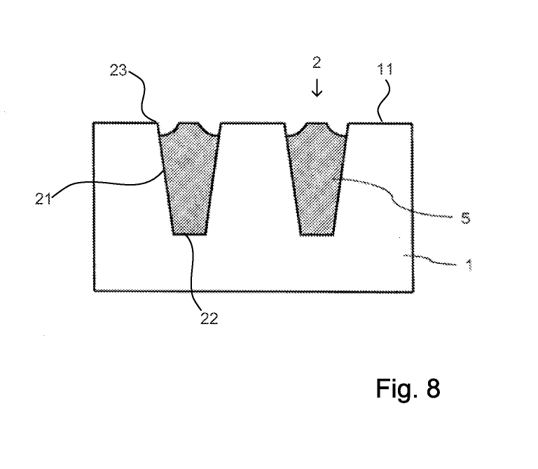

FIGS. 8-10 are cross-sectional views illustrating a method of manufacturing a transistor according to the second embodiment.

First, by the method similar to that in the first embodiment, the semiconductor substrate 1 and the element isolation trench 2 are formed. Thereafter, the element isolation trench 2 is filled with the element isolation insulating film 5 as shown in FIG. 8 and is flattened by CMP. Further, for example, by etching the element isolation insulating film 5 using a dilution hydrofluoric acid solution, upper angular parts of the element isolation trench 2 are exposed.

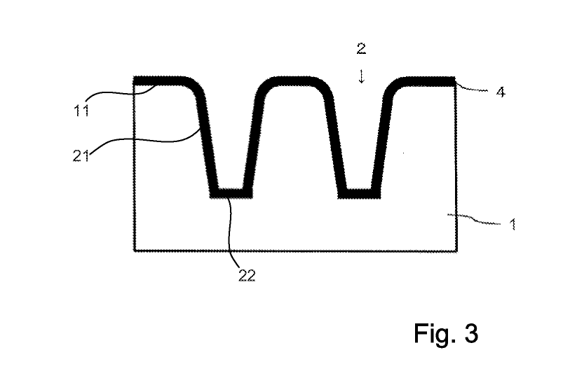

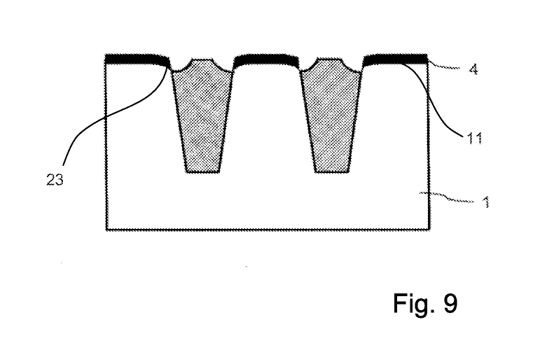

Next, Hafnium (Hf) 3 in the amount of 1E15 atoms/cm², for example, is deposited by spattering. As long as the Hf is deposited in an area including at least the upper angular part 23 of the element isolation trench 2, it is practical. The amount of Hf deposited may be equal to or less than 1 atomic layer. In addition, as shown in FIG. 9, by performing an oxidation similar to that shown in FIG. 3 in the first embodiment, the oxide film 4 is formed to cover surfaces 11 of the semiconductor substrate 1 and the upper angular parts 23 of the element isolation trench 2. As a result of the progress of oxidation using the oxygen radicals, the upper angular parts 23 of the element isolation trench 2 are rounded.

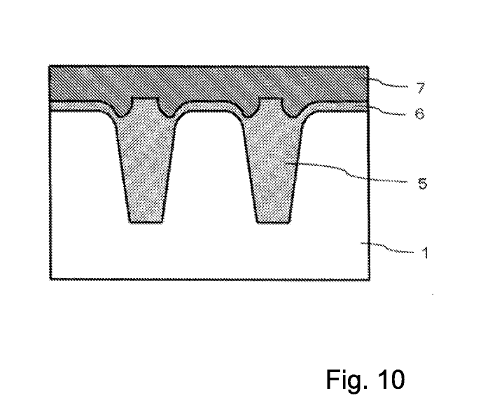

Thereafter, as shown in FIG. 10, the gate insulating film 6 and the gate electrode 7 are formed after the Hf and the oxide film 4 are removed. Then, a transistor is formed by performing ion injection or the like using a known method.

With the transistor formed as discussed above, because the radius of curvature of the upper angular part 23 of the element isolation trench 2 is large, degradation of electric properties of the transistor can be suppressed.

Table 1 below illustrates the steps of the processes and the differences between the first and second embodiments.

TABLE 1

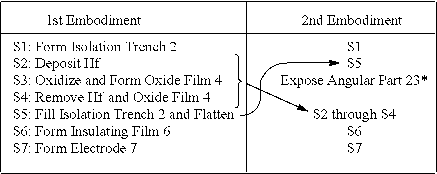

*indicates a step not included in the first embodiment

In addition, the element isolation insulating film 5 is etched using the dilution hydrofluoric acid solution in the present embodiment. However, the etching can be omitted if a divot is generated during the CMP process that flattens the element isolation insulating film and if the upper angular part 23 of the element isolation trench 2 is exposed.

Further, in the embodiment, the Hf is deposited while the upper angular part 23 of the element isolation trench 2 is exposed. However, it is not necessary that the upper angular part is entirely exposed. The upper angular part may be covered with an oxide film with a thickness of approximately 2 nm. As apparent from FIG. 7, similar effects can be obtained in a case where the Hf is directly deposited on the oxide film.

In addition, instead of Hf, a film that contains Hf may be formed. Moreover, needless to say, any metal that promotes generation of the oxygen radicals can be used.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and the spirit of the inventions.

What is claimed is:

1. A method of manufacturing a semiconductor device, comprising:
a process to form an element isolation trench on a semiconductor substrate, the element isolation trench having a crystal plane orientation that is different from a crystal plane orientation on a surface of the semiconductor substrate;
a process to deposit, on the semiconductor substrate, one of a metal that promotes generation of oxygen radicals and a metal containing film that promotes generation of the oxygen radicals;
a process to oxidize the semiconductor substrate; and
a process to remove the one of the metal and the metal containing film.

2. The method of manufacturing the semiconductor device according to claim 1, further comprising:
a process to form an insulating film in the element isolation trench after the process to remove the one of the metal and the metal containing film.

3. The method of manufacturing the semiconductor device according to claim 2, wherein
the metal is one of hafnium and zirconium.

4. The method of manufacturing the semiconductor device according to claim 2, wherein
the metal containing film is one of a metal oxide film and a metal silicate film.

5. The method of manufacturing the semiconductor device according to claim 2, wherein
the element isolation trench includes an angular part, and
in the process to deposit, one of the metal and the metal containing film is disposed in an area that includes at least the angular part.

6. The method of manufacturing the semiconductor device according to claim 2, wherein
the oxidizing process is a thermal oxidation.

7. The method of manufacturing the semiconductor device according to claim 4, wherein
the metal oxide film is HfO₂ and the metal silicate film is HfSiOx.

8. The method of manufacturing the semiconductor device according to claim 2, wherein
in the process to oxidize, an oxide film is formed on the surface of the semiconductor substrate and the element isolation trench.

9. The method of manufacturing the semiconductor device according to claim 8, wherein
in the process to remove, the oxide film is also removed.

10. The method of manufacturing the semiconductor device according to claim 1, further comprising:
a process to form an insulating film in the element isolation trench before the process to deposit one of the metal and the metal containing film.

11. The method of manufacturing the semiconductor device according to claim 10, wherein
the element isolation trench includes an angular part, and
in the process to deposit, the one of the metal and the metal containing film is disposed in an area that includes at least the angular part.

12. The method of manufacturing the semiconductor device according to claim 11, wherein
in the process to form the insulating film, the angular part is exposed.

13. The method of manufacturing the semiconductor device according to claim 10, wherein
the metal is one of hafnium and zirconium.

14. The method of manufacturing the semiconductor device according to claim 10, wherein
the metal containing film is one of a metal oxide film and a metal silicate film.

15. The method of manufacturing the semiconductor device according to claim 10, wherein
the process to oxidize is a thermal oxidation process.

16. The method of manufacturing the semiconductor device according to claim 14, wherein
the metal oxide film is HfO₂ and the metal silicate film is HfSiOx.

17. The method of manufacturing the semiconductor device according to claim 10, wherein
in the process to oxidize, an oxide film is formed on the surface of the semiconductor substrate and the element isolation trench.

18. The method of manufacturing the semiconductor device according to claim 17, wherein
in the process to remove, the oxide film is also removed.
